(19) United States
(12) Patent Application Publication
(10) Pub. No.: US 2012/0006400 A1
(43) Pub. Date: Jan. 12, 2012

(54) SOLAR MODULE DEVICE AND EDGE SEALING COATING METHOD THEREOF

(75) Inventors: Yi-Wen Tai, Hsinchu City (TW); Cheng-Pei Huang, Taipei City (TW)

(73) Assignee: Du Pont Apollo Limited, Hong Kong (HK)

(21) Appl. No.: 13/175,883

(22) Filed: Jul. 3, 2011

(30) Foreign Application Priority Data
Jul. 6, 2010 (CN) 201010222552.9

(51) Int. Cl. H01L 31/0203; H01L 31/18

(52) U.S. Cl. 136/256; 156/109

(57) ABSTRACT

A solar module device and edge sealing coating method thereof are provided, which adopt a light curable adhesive to replace conventional hot melt glue and produce an unexpected effect, so as to uniformly and precisely coat the adhesive on an edge area of a substrate assembly and further reduce the cost.

### RELATED APPLICATIONS

This application claims priority to China Application Serial Number 201010222552.9, filed Jul. 6, 2010, which is herein incorporated by reference.

### BACKGROUND

1. Field of Invention

The present invention relates to an edge sealing coating method. More particularly, the present invention relates to an edge sealing coating method of a solar module device.

2. Description of Related Art

In the prior art, after a solar cell module is fabricated, in order to prevent moisture from penetrating into the solar cell module through its edges, mostly, hot melt glue is adopted to perform an edge sealing coating process. Specifically, the hot melt glue is normally used as an adhesive. After being heated, the hot melt glue is coated on the edges of two overlapped glass substrates (or a glass substrate and a back plate). After being cooled down, the hot melt glue is cured and agglutinates the edges of the two overlapped glass substrates, so as to prevent moisture from penetrating into the interior of the solar cell module through the clearance.

However, a hot melt glue coating machine with necessary heating equipment is heavy and is hard to be controlled, and meanwhile a glue gun cannot be directly controlled manually due to over-high temperature. Furthermore, since the hot melt glue needs to be heated and itself has high viscosity and the hot melt glue gun cannot have an injection orifice as fine as a needle tip, the precision of coating cannot be ensured.

Due to the foregoing reasons, a conventional technique using the hot melt glue as an adhesive for performing an edge sealing substrate assembly is heavy and clumsy in operation and lacks flexibility, and also lacks coating precision. Particularly, when two overlapped large glass substrates (such as the glass substrates of the solar module device) are bonded as a substrate to assembly, the edges of the substrate assembly are easy to be tilted due to its large area, and thus it is difficult to coat the adhesive therein uniformly on the edges of the substrate assembly.

If the adhesive is not uniformly coated on the edges of the substrate assembly, the edges of the substrate assembly cannot be sealed, and thus the moisture will penetrate and influence the power generation efficiency of the solar module device. Thus, the yield is reduced and the manufacturing cost is accordingly increased.

Therefore, there is a need to develop a technique of uniformly coating the adhesive on the edges of the substrate assembly.

### SUMMARY

The summary aims to provide a brief description of the disclosure so that readers can understand the disclosure fundamentally. The summary does not describe the disclosure completely, and does not intend to specify the important/critical elements of the embodiments of the present invention or limit the scope of the present invention.

According to an aspect of the present invention, a solar module device is provided, and includes: a first glass substrate; a solar cell layer formed on the first glass substrate; an encapsulating material layer disposed on the solar cell layer; a second glass substrate covering the encapsulating material layer, wherein the first glass substrate and the second glass substrate are bonded by a light curable adhesive coated on an edge area of the first glass substrate and the second glass substrate, so as to seal a sandwiched space containing the solar cell layer and the encapsulating material layer between the first glass substrate and the second glass substrate, and the light curable adhesive is cured by irradiation of a light source having a specific wavelength.

According to an embodiment of the present invention, a solar module device is provided, in which the edges of the first glass substrate and the is second glass substrate are with round angles, the edge area formed by overlapping and connecting the edges of the first glass substrate and the second glass substrate integrally forms a V-shaped groove, and the light curable adhesive is coated on the V-shaped groove by using a glue gun head of a glue gun.

According to another embodiment of the present invention, a solar module device is provided, wherein the light curable adhesive is a photo-curing resin.

According to another aspect of the present invention, an edge sealing coating method of a solar module device is provided, and includes the following steps: forming a solar cell layer on a first glass substrate; disposing an encapsulating material layer on the solar cell layer; covering the encapsulating material layer with a second glass substrate; coating a light curable adhesive on an edge area of the first glass substrate and the second glass substrate; and irradiating the light curable adhesive by using a light source having a specific wavelength, such that the light curable adhesive is cured to seal a sandwiched space containing the solar cell layer and the encapsulating material layer between the first glass substrate and the second glass substrate.

According to an embodiment of the present invention, an edge sealing coating method of a solar module device is provided, wherein in the aforementioned step of coating the light curable adhesive, a glue gun head of a glue gun is used to coat the light curable adhesive on the edge area of the first glass substrate and the second glass substrate.

According to another embodiment of the present invention, an edge sealing coating method of a solar module device is provided, wherein in the is above step of coating the light curable adhesive, the light curable adhesive is a photo-curing resin.

These and other features, aspects, and advantages of the present invention will become better understood with reference to the following description and appended claims.

### BRIEF DESCRIPTION OF THE DRAWINGS

The above and other objectives, features, advantages and embodiments of the present invention can be more fully understood with reference to the accompanying drawings as follows:

FIG. 1 is a schematic view of a solar module device according to an embodiment of the present invention; and

FIG. 2 is a schematic view of an edge sealing glue head of the solar module device of FIG. 1 on which edge sealing coating has been performed according to another embodiment of the present invention.

### DETAILED DESCRIPTION

To make the contents of the present invention more thorough and complete, the following illustrative description is given with regard to the implementation aspects and embodiments of the present invention, which is not intended to limit the scope of the present invention. The features of the embodiments and the steps of the method and their sequences that constitute and implement the embodiments are described. However, other embodiments may be used to achieve the same or equivalent functions and step sequences.

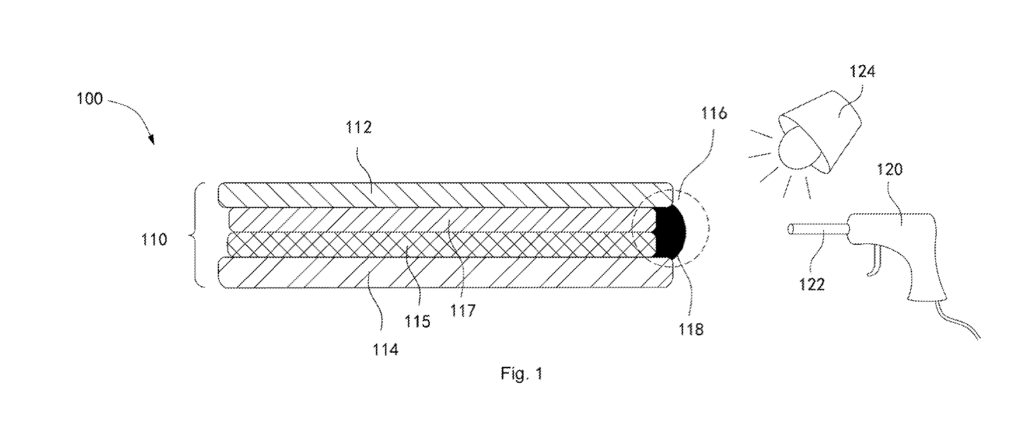

FIG. 1 is a schematic view of a solar module device according to an embodiment of the present invention. A solar cell layer 115 is formed on a first glass substrate 114, and then an encapsulating material layer 117, for example, ethylene-vinyl acetate (EVA), is placed on the solar cell layer 115. Thereafter, a second glass substrate 112 is placed on the encapsulating material layer 117. Then, press bonding is performed to finish the pre-fabrication of the solar module device 100. Thereafter, the post-processes of soldering, framing, etc. are carried out.

In other words, the solar cell layer 115 and the encapsulating material layer 117 are contained in a sandwiched space between the first glass substrate 114 and the second glass substrate 112. In order to seal the sandwiched space to prevent moisture penetration, a light curable adhesive 118 is coated on an edge area 116 of the first glass substrate 114 and the second glass substrate 112, and then is irradiated by a light source 124 having a specific wavelength for curing the light curable adhesive 118, thereby sealing the sandwiched space to seal the solar cell layer 115 and the encapsulating material layer 117 inside the sandwiched space.

The edges of the first glass substrate 114 and the second glass substrate 112 may be with round angles, and the thickness of the solar cell layer 115 and the encapsulating material layer 117 is smaller than that of the first glass substrate 114 and the second glass substrate 112 (for illustration, the components of FIG. 1 are not drawn to scale, and the solar cell layer 115 and the encapsulating material layer 117 are drawn thicker than actual layers), and thus an overlapped and connected edge area 116 integrally forms an approximately V-shaped groove. The light curable adhesive 118 is coated on the approximately V-shaped groove through a glue gun head 122 of a glue gun 120, and is irradiated by a light source 124 having a specific wavelength for curing the light curable adhesive 118 on the V-shaped groove. The light curable adhesive 118 may be a photo-curing resin.

As can be known from the above description, the present invention may omit the clumsy heating equipment and overcome the problem of over-high temperature and the difficulty in directly controlling the glue gun manually. Moreover, the light curable adhesive can be coated by a thin glue gun head, and thus the precision of coating is greatly improved.

Therefore, the present invention has another advantage of using light and convenient coating equipment and precisely controlling the glue gun head, and thus the adhesive can be uniformly and precisely coated on the edges of the substrate assembly, and further the cost can be reduced.

According to another aspect of the present invention, an edge sealing coating method for the solar module device is provided.

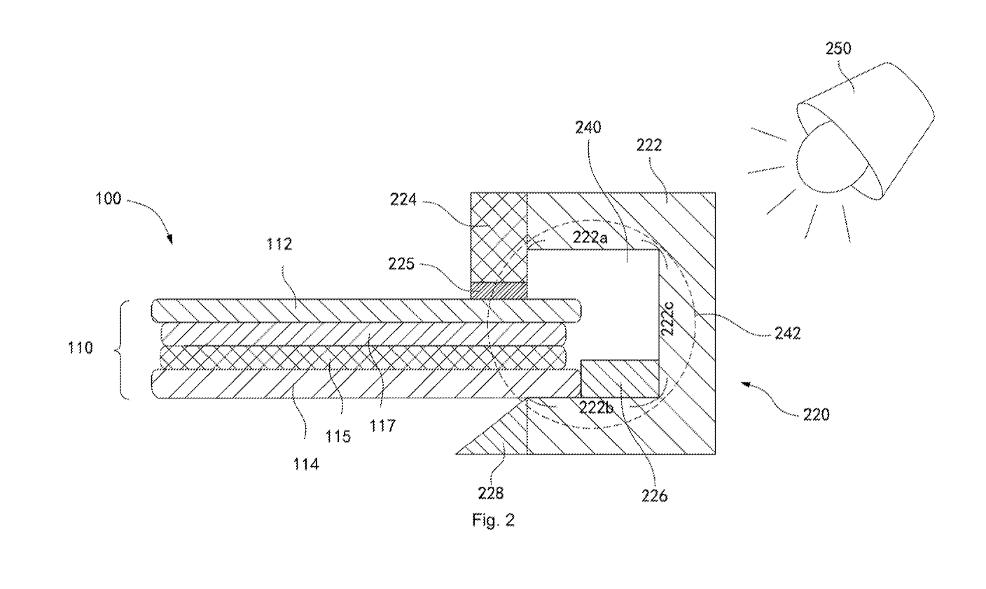

FIG. 2 is a schematic view of an edge sealing glue head of the solar module device 100 of FIG. 1 on which edge sealing coating has been performed according to another embodiment of the present invention. The solar module device 100 includes a substrate assembly 110 including a first glass substrate 114, a solar cell layer 115, an encapsulating material layer 117 and a second glass substrate 112 from bottom to top.

The edge sealing glue head includes a glued frame 220 having a groove 222 along a length direction, and a fixing strip 224, wherein the groove 222 has a first side edge 222a, a second side edge 222b and a bottom 222c; and the fixing strip 224 is in an elongated shape and connected to the first side edge 222a of the groove 222 along the length direction of the glued frame 220, thereby contacting the substrate assembly 110 which is inserted into the groove 222.

The fixing strip 224, the groove 222 and the substrate assembly 110 collaboratively define a space 240 in a contact area 242 of the substrate assembly 110 and the glued frame 220, and an adhesive may be filled in the space 240 for performing the edge sealing coating process on the edges of the substrate assembly 110.

Therefore, the present invention has an advantage of accurately defining the space 240 accommodating the adhesive by use of the fixing strip 224, thereby precisely controlling the coating range and dosage of the adhesive.

Likewise, the light curable adhesive may be a photo-curing resin.

Optionally, the portion of the fixing strip 224 contacting the substrate assembly 110 may further include an elastic pad 225 which has elasticity for avoiding damaging the substrate assembly 110 when the substrate assembly 110 is being assembled into the groove 222.

When the substrate assembly 110 is being assembled into the groove 222, the elastic pad 225 is placed in a rather high temperature environment, and thus the elastic bumper 225 is preferably a heat resistant material.

Furthermore, a fixing strip 224 may be additionally attached to the groove 222, and may be integrally formed with the groove 222 to become a portion of the groove 222. The fixing strip 224 may also have the same material as that of the groove 222.

Optionally, the groove 222 may further include an obstruction block 226 disposed between the substrate assembly 110 and the bottom 222c of the groove 222, thereby controlling a coating range of the adhesive on the bottom 222c of the groove 222.

Furthermore, the second side edge 222b of the groove 222 has a bevel 228 for allowing the substrate assembly 110 to be easily inserted into the groove 222 along the bevel 228, thereby preventing the deformation of the substrate assembly 110.

Although the present invention has been described in considerable detail with reference to certain embodiments thereof, other embodiments are possible. Various alternations and modifications can be made to these certain embodiments by those skilled in the art without departing from the spirit and scope of the present invention. Such alternations and modifications are intended to fall within the scope of the appended claims.

What is claimed is:

1. An edge sealing coating method of a solar module device, comprising:
forming a solar cell layer on a first glass substrate;
disposing an encapsulating material layer on the solar cell layer;
covering the encapsulating material layer with a second glass substrate;
coating a light curable adhesive on an edge area of the first glass substrate and the second glass substrate; and
irradiating the light curable adhesive by using a light source having a specific wavelength to cure the light curable adhesive, so as to seal a sandwiched space containing the solar cell layer and the encapsulating material layer between the first glass substrate and the second glass substrate.

2. The edge sealing coating method of claim 1, wherein,
in the step of coating the light curable adhesive, the light curable adhesive is coated on the edge area of the first glass substrate and the second glass substrate.

3. The edge sealing coating method of claim 1, wherein,
in the step of coating the light curable adhesive, the light curable adhesive is a photo-curing resin.

4. A solar module device, comprising:
a first glass substrate;
a solar cell layer formed on the first glass substrate;
an encapsulating material layer disposed on the solar cell layer; and
a second glass substrate covering the encapsulating material layer,
wherein the first glass substrate and the second glass substrate are bonded by a light curable adhesive coated on an edge area of the first glass substrate and the second glass substrate, so as to seal a sandwiched space containing the solar cell layer and the encapsulating material layer between the first glass substrate and the second glass substrate;
wherein the light curable adhesive is cured by irradiation of a light source having a specific wavelength.

5. The solar module device of claim 4, wherein all edges of the first glass substrate and the second glass substrate are with round angles, and the edge area formed by overlapping and connecting the edges integrally forms a V-shaped groove, and the light curable adhesive is coated on the V-shaped groove by using a glue gun head of a glue gun.

6. The solar module device of claim 4, wherein the light curable adhesive is a photo-curing resin.
